(19) United States
(12) Patent Application Publication
(10) Pub. No.: US 2026/0023915 A1
(43) Pub. Date: Jan. 22, 2026

(54) METHOD FOR DIRECT AND VISUAL DETERMINATION OF OPTIMAL SOLUTION FOR ELECTRONIC DEVICE WITH RESPONSE TO TWO OR MORE ORTHOGONAL INPUTS

(71) Applicant: Qorvo US, Inc., Greensboro, NC (US)

(72) Inventor: Tom A. Kwa, San Jose, CA (US)

(21) Appl. No.: 19/257,718

(22) Filed: Jul. 2, 2025

Related U.S. Application Data
(60) Provisional application No. 63/672,839, filed on Jul. 18, 2024.

(51) Int. Cl. G06F 30/398; G01L 1/18; G01L 5/162

(52) U.S. Cl. CPC G06F 30/398; G01L 1/18; G01L 5/162

(57) ABSTRACT

The present disclosure relates to a method of determining an optimal solution for an electronic device with response to two or more orthogonal input loads. The disclosed method starts with generating first and second conditional plots of the electronic device based on first and second criteria, respectively. Herein, a first characteristic within the first conditional plot meets the first criterion when a first load is applied to the electronic device, while a second characteristic within the second conditional plot meets the second criterion when a second load is applied to the electronic device. Generating the first and second conditional plots are independent from each other, and the second criterion is different from the first criterion. An intersection plot is then generated by overlaying the first and second conditional plots. The intersection plot indicates whether the electronic device has one or more solution locations satisfying both the first and second criteria.

### RELATED APPLICATIONS

This application claims the benefit of provisional patent application Ser. No. 63/672,839, filed Jul. 18, 2024, the disclosure of which is hereby incorporated herein by reference in its entirety.

### FIELD OF THE DISCLOSURE

The present disclosure relates to a method of directly and visually determining an optimal solution for an electronic device, especially for a solution that needs to meet two or more criteria.

### BACKGROUND

In many electronic device designs, such as sensor designs, the placement of the sensing elements within a sensor is critical to the performance of the electronic device. For a non-limiting example, a piezoresistive force sensor is based on piezoresistors, which convert mechanical stress resulting from a force applied to the sensor into electrical outputs. Typically, the level of the mechanical stress is not uniform along the surface of the piezoresistive force sensor where the piezoresistors are located. To produce an adequate response to the force and hence a large electrical output (i.e., to achieve good performance of the piezoresistive force sensor), the piezoresistors are desired to be placed in one or more locations where the mechanical stress is large.

On the other hand, due to differences in thermal coefficient of expansion (TCE) among various materials from which the piezoresistive force sensor is made, and due to differences in TCE between the piezoresistive force sensor and a substrate (to which the sensor is attached) or between the piezoresistive force sensor and a package structure (in which the sensor is mounted), temperature changes will also cause mechanical stress. Since the piezoresistors cannot distinguish the undesirable temperature-induced mechanical stress from the desirable force-induced mechanical stress, the electrical output of the piezoresistors is an inseparable output converted from a combination of the undesirable temperature-induced mechanical stress and the force-induced mechanical stress. To minimize undesired temperature impact, the piezoresistors are desired to be placed in one or more locations where the temperature-induced mechanical stress is small.

Accordingly, it is therefore an object of the present disclosure to provide a method of determining optimal locations for the piezoresistors within the piezoresistive force sensor, at which both the force-induced output and the temperature-induced output can meet requirements for good performance of the piezoresistive force sensor. More broadly, an object of the present disclosure is to provide a method of determining an optimal solution for an electronic device which needs to meet two or more criteria.

### SUMMARY

The present disclosure relates to a method of directly and visually determining an optimal solution for an electronic device which needs to meet two or more criteria. The disclosed method starts with generating a first conditional plot and a second conditional plot of the electronic device based on a first criterion and a second criterion, respectively. Herein, a first characteristic within the first conditional plot meets the first criterion when a first load is applied to the electronic device, while a second characteristic within the second conditional plot meets the second criterion when a second load is applied to the electronic device. Generating the second conditional plot is independent from generating the first conditional plot, and the second criterion is different from the first criterion. An intersection plot is then generated by overlaying the first conditional plot with the second conditional plot. The intersection plot indicates whether the electronic device has one or more solution regions that satisfy both the first criterion and the second criterion.

In one embodiment of the method, the first characteristic and the second characteristic are a same type of characteristic, while the first load is different from the second load. Herein, each of the first load and the second load is one of an electrical input, a thermal input, a mechanical input, and a magnetic input.

In one embodiment of the method, the first characteristic is different from the second characteristic.

According to one embodiment, the method further includes generating one or more additional conditional plots of the electronic device based on one or more additional criteria, respectively, before generating the intersection plot. Herein, the one or more additional criteria are different from the first criterion and the second criterion.

In one embodiment of the method, generating the one or more additional conditional plots is independent from generating the first conditional plot and generating the second conditional plot. The intersection plot is generated by overlaying the first conditional plot, the second conditional plot, and the one or more additional conditional plots. Herein, the intersection plot indicates whether the electronic device has one or more solution regions that satisfy the first criterion, the second criterion, and the one or more additional criteria.

In one embodiment of the method, generating the first conditional plot of the electronic device includes calculating a first characteristic map of the electronic device subject to the first load applied to the electronic device, and plotting one or more regions on the first characteristic map, within which the first characteristic induced by the first load meets the first criterion.

In one embodiment of the method, generating the second conditional plot of the electronic device includes calculating a second characteristic map of the electronic device subject to the second load applied to the electronic device, and plotting one or more regions on the second characteristic map, within which the second characteristic induced by the second load meets the second criterion.

In one embodiment of the method, the electronic device is a piezoresistive sensor. The first characteristic is a first stress level induced by the first load, while the second characteristic is a second stress level induced by the second load. The first load and the second load are different, each of which is one of an electrical input, a thermal input, a mechanical input, a magnetic input, and an optical input.

In one embodiment of the method, the electronic device is an optical sensor. The first characteristic is a first current induced by the first load, while the second characteristic is a second current induced by the second load. The first load and the second load are different, each of which is one of an optical input and a thermal input.

In one embodiment of the method, when the one or more solution regions exist, the intersection plot further indicates how many solution regions satisfy both the first criterion and the second criterion, and where the one or more solution regions are located.

In addition, the present disclosure also specifies a method of determining an optimal solution for a piezoresistive force sensor. The method starts with generating a force-induced stress (FIS) conditional plot of the piezoresistive force sensor based on a first criterion and generating a temperature-induced stress (TIS) conditional plot of the piezoresistive force sensor based on a second criterion. Herein, an FIS level within the FIS conditional plot meets the first criterion when a force input is applied to the piezoresistive force sensor. A TIS level within the TIS conditional plot meets the second criterion when a temperature increase is applied to the piezoresistive force sensor. Generating the TIS conditional plot is independent from generating the FIS conditional plot. An intersection plot is then generated by overlaying the FIS conditional plot with the TIS conditional plot. The intersection plot indicates whether the piezoresistive force sensor has one or more solution regions that satisfy both the first criterion and the second criterion.

In one embodiment of the method, the first criterion is that an absolute value of the FIS level is larger than a minimum required value corresponding to the applied force input. The second criterion is that an absolute value of the TIS level is smaller than a maximum required value corresponding to the applied temperature increase.

In one embodiment of the method, generating the FIS conditional plot includes calculating stress distributions for the piezoresistive force sensor subject to the force input applied to the piezoresistive force sensor, such that an FIS map of the piezoresistive force sensor is confirmed, and plotting one or more regions on the FIS map, within which the FIS level meets the first criterion.

In one embodiment of the method, generating the TIS conditional plot includes calculating stress distributions for the piezoresistive force sensor subject to the temperature increase applied to the piezoresistive force sensor, such that a TIS map of the piezoresistive force sensor is confirmed, and plotting one or more regions on the TIS map, within which the TIS level meets the second criterion.

In one embodiment of the method, when the one or more solution regions exist, the intersection plot further indicates how many solution regions satisfy both the first criterion and the second criterion, and where the one or more solution regions are located.

According to one embodiment, the method further includes placing piezoresistors in the one or more solution regions of the piezoresistive force sensor.

According to one embodiment, a communication device includes a control system, a baseband processor, user interface circuitry configured to communicate with the baseband processor and/or the control system, and a physical interface component. The physical interface component includes at least one piezoresistive sensor, which is configured to measure external loads to the physical interface component and to transfer electrical signals to the user interface circuitry corresponding to the external loads, such that the electrical signals induced by the external loads are capable of being processed in the baseband processor and/or the control system. Herein, measuring the external loads includes generating a first conditional plot of the at least one piezoresistive sensor based on a first criterion, and generating a second conditional plot of the at least one piezoresistive sensor based on a second criterion. A first characteristic within the first conditional plot meets the first criterion when a first load of the external loads is applied to the at least one piezoresistive sensor, while a second characteristic within the second conditional plot meets the second criterion when a second load of the external loads is applied to the at least one piezoresistive sensor. The second criterion is different from the first criterion, and generating the second conditional plot is independent from generating the first conditional plot. Additionally, measuring the external loads further includes generating an intersection plot by overlaying the first conditional plot with the second conditional plot. The intersection plot indicates whether the at least one piezoresistive sensor has one or more solution regions that satisfy both the first criterion and the second criterion.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 provides a flow diagram that illustrates an exemplary process to determine optimal locations for piezoresistors in a piezoresistive force sensor according to some embodiments of the present disclosure.

FIGS. 2-8 illustrate the steps associated with the process shown in FIG. 1.

FIG. 9 provides a flow diagram that illustrates an exemplary process to determine an optimal solution for an electronic device according to some embodiments of the present disclosure.

FIG. 10 illustrates a block diagram of a communication device with an interface element, which includes a piezoresistive sensor provided by the determination process shown in FIG. 1 according to some embodiments of the present disclosure.

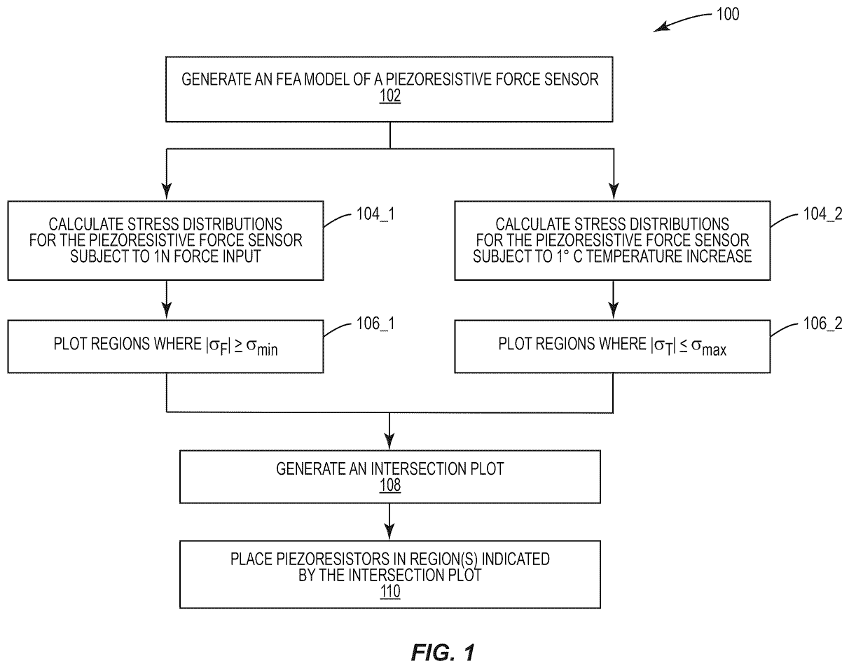

It will be understood that for clear illustrations, FIGS. 1-10 may not be drawn to scale.

### DETAILED DESCRIPTION

The embodiments set forth below represent the necessary information to enable those skilled in the art to practice the embodiments and illustrate the best method of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

For sensor designs, where sensing elements are placed is critical to the performance of a sensor. For a non-limiting example, operational performance of a piezoresistive force sensor is closely dependent on locations of piezoresistors placed within the piezoresistive force sensor. The piezoresistive force sensor is designed to quantify force by sensing corresponding change in electrical resistance of semiconductive materials. Typically, one or more piezoresistors are formed from silicon on a surface of the piezoresistive force sensor, which convert mechanical stress resulting from the force applied to the piezoresistive force sensor into electrical resistance changes. If the piezoresistors are configured in a Wheatstone bridge, the electrical resistance changes produce voltage outputs. To produce the largest response to the applied force and hence the largest electrical output (e.g., the largest voltage outputs), the piezoresistors must be placed in a location where the force-induced mechanical stress is highest. However, if such location is not available for placement, then the piezoresistors are at least placed in a location where a required minimum electrical output will be produced (a required minimum force-induced mechanical stress will be sensed) for a given force input.

Besides the force applied to the piezoresistive force sensor, temperature changes (due to TCE differences within or adjacent to the piezoresistive force sensor) may also cause mechanical stress and thereby result in electrical outputs of the piezoresistors. Since the piezoresistors cannot distinguish the undesirable temperature-induced mechanical stress from the desirable force-induced mechanical stress, the electrical output of the piezoresistors is an inseparable output of a combination of the temperature-induced output (TIO in [mV/V/° C.]) and the force-induced output (FIO in [mV/V/N]). As such, the TIO may only be minimized by placing the piezoresistors at locations where the mechanical stress due to temperature changes is zero. However, if such a location is not available, then the piezoresistors are at least placed at a location where no more than a permitted maximum temperature-induced output will be produced (a permitted maximum temperature-induced mechanical stress will be sensed) for a given temperature change.

Unfortunately, on the surface of the piezoresistive force sensor, where the temperature-induced mechanical stress is zero, the force-induced mechanical stress is typically also close to zero. Conversely, in locations where the temperature-induced mechanical stress is highest, the force-induced mechanical stress is typically also high. In order to determine optimal locations for the piezoresistors on the surface of the piezoresistive force sensor, it is required to simultaneously meet both FIO minimum and TIO maximum limits. A conventional process to find locations that simultaneously meet both the FIO minimum and TIO maximum limits is repetitive and iterative. Typically, one or more locations with the highest FIO are found first, and then a TIO simulation at these highest-FIO locations is run to check whether the TIO limit is met. If not, the process continues by selecting one or more locations with the second highest FIO and running a second TIO simulation at these second highest-FIO locations to check whether the TIO limit is met, and so on. This highly iterative process has no certainty that if a solution is found, that the solution is an optimal one, or, if no solution is found, that there is indeed none.

As such, there is a need to identify all locations on the surface of the piezoresistive force sensor to place the piezoresistors—if there is any available—where the FIO is no less than the required minimum and where, simultaneously, the TIO is no more than the permitted maximum. The present disclosure provides a method for direct and visual determination of all optimal locations of the piezoresistors.

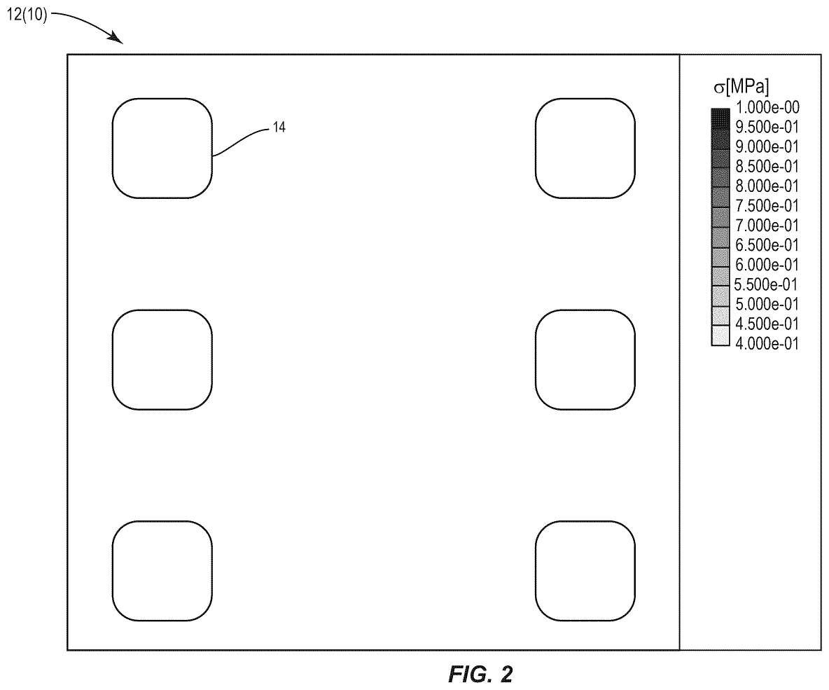

FIG. 1 provides a flow diagram that illustrates an exemplary process 100 of determining optimal locations for piezoresistors on a surface of a piezoresistive force sensor according to some embodiments of the present disclosure. FIGS. 2-8 illustrate the steps associated with the process 100 shown in FIG. 1. Although the flow diagram and the associated steps are illustrated in a series, they are not necessarily order-dependent. Some steps may be done in a different order from that presented. Further, processes within the scope of this disclosure may include fewer or more steps than those illustrated in FIG. 1.

Initially, a finite element analysis (FEA) model of a piezoresistive force sensor 10 is generated (step 102). The FEA model is configured to simulate mechanical stress fields of the piezoresistive force sensor 10 due to any external input loads (e.g., forces, temperature changes) applied to the piezoresistive force sensor 10. FIG. 2 illustrates an initial stress field map 12 of the piezoresistive force sensor 10 when no external input load is applied to the piezoresistive force sensor 10. Herein, the initial stress field map 12 of the piezoresistive force sensor 10 has the same size and shape as a top view of the piezoresistive force sensor 10 and indicates stress levels across the entire piezoresistive force sensor 10.

For the purpose of this illustration, the piezoresistive force sensor 10 has a rectangular shape and includes 2×3 solder bumps 14. In different applications, the piezoresistive force sensor 10 may have a different shape (e.g., a square or a circle in a horizontal plane) and includes fewer or more solder bumps 14 with a different layout. For the initial stress field map 12, since there is no external load applied to the piezoresistive force sensor 10, the initial stress field map 12 of the piezoresistive force sensor 10 indicates a uniform zero stress level. In some embodiments, the piezoresistive force sensor 10 may be a silicon piezoresistive force sensor (such as a silicon micro-electromechanical systems (MEMS) silicon force sensor), and piezoresistors to be used in the piezoresistive force sensor 10 may be semiconductor elements, which are very sensitive to stress variation and capable of converting stress variation to electrical outputs.

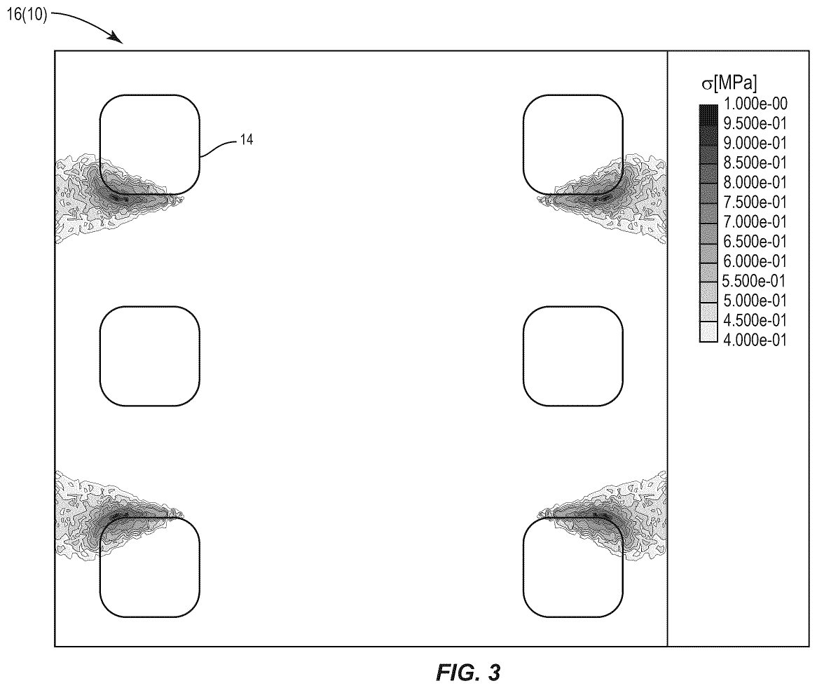

Next, stress distributions are calculated/estimated for the piezoresistive force sensor 10 subject to a force input applied to the piezoresistive force sensor 10 by utilizing the FEA model (step 104_1). FIG. 3 illustrates a force-induced stress (FIS) map 16 of the piezoresistive force sensor 10, which indicates the stress distributions throughout the entire piezoresistive force sensor 10 (in the horizontal plane) when 1-newton (1N) force is applied to the piezoresistive force sensor 10. Herein, “1N” force is a normalized value. In different applications, different force strengths can be used in the simulation.

Due to the non-uniform structure of the piezoresistive force sensor 10 (e.g., due to the presence of the solder bumps 14), the mechanical stress induced by the 1N force is uneven across the piezoresistive force sensor 10. For the purpose of this illustration, the highest stress levels induced by the 1N force (maximum positive stress or maximum negative stress) occur near the topmost solder bumps 14 and the bottommost solder bumps 14. In different applications, the highest stress levels induced by the 1N force may occur at different locations on the piezoresistive force sensor 10.

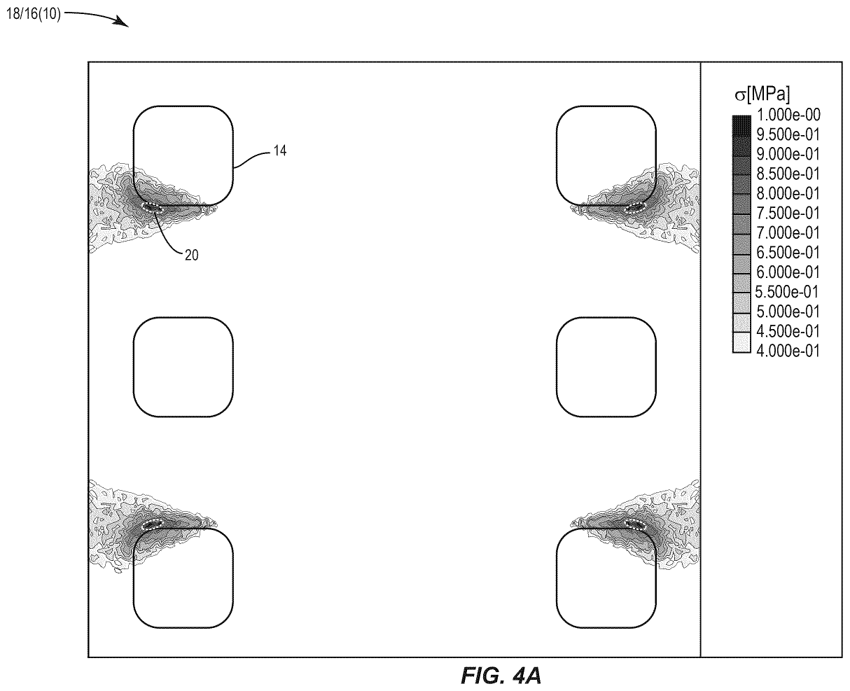

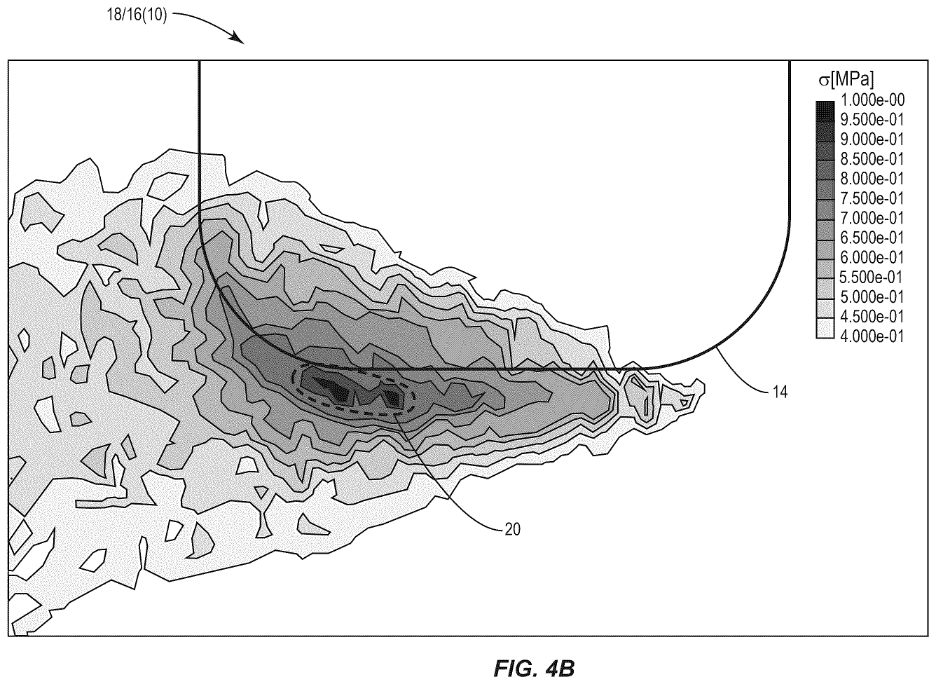

Once the 1N force-induced stress distributions are calculated (i.e., the FIS map 16 is confirmed), one or more regions, where the absolute value of the 1N force-induced stress level |σ_{F}| is larger than or equal to σₘᵢₙ, are plotted (step 106_1). σₘᵢₙ is a positive number and is a minimum required stress level corresponding to the applied 1N force (e.g., σₘᵢₙ=8.5e-01 MPa). FIG. 4A illustrates an FIS conditional plot 18 with the plotted |σ_{F}|≥σₘᵢₙ regions 20 (the FIS map 16 is added as a background for illustrative reference), while FIG. 4B illustrates an enlarged portion of the FIS conditional plot 18. For the purpose of these illustrations, there are four discrete plotted |σ_{F}|≥σₘᵢₙ regions 20, and each plotted |σ_{F}|≥σₘᵢₙ regions 20 has an oval-like shape and is located near the topmost solder bumps 14 and the bottommost solder bumps 14. In different applications, the plotted |σ_{F}|≥σₘᵢₙ regions 20 may have different numbers, different shapes, and/or different sizes depending on the force-induced stress distributions on the piezoresistive force sensor 10.

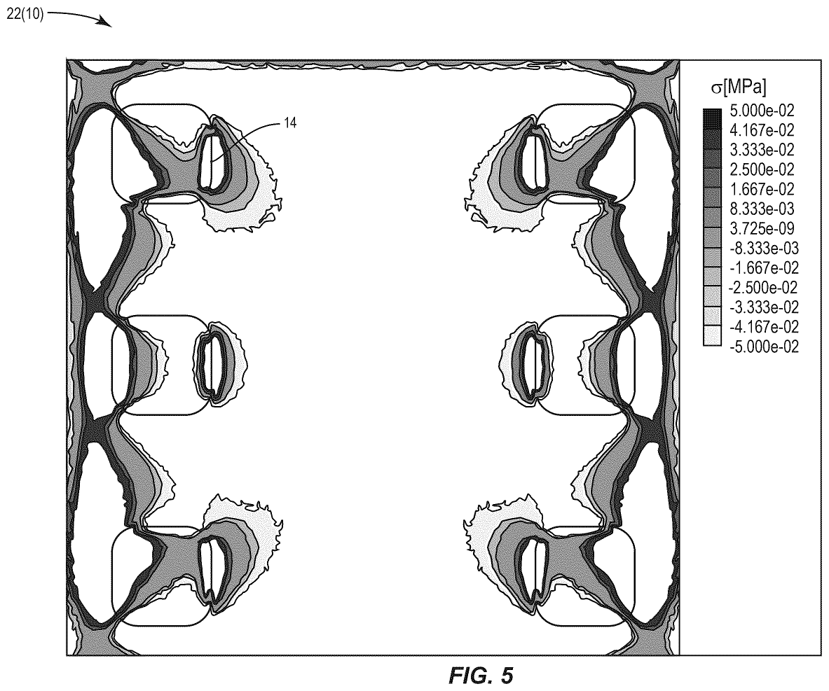

After the FEA model of the piezoresistive force sensor 10 is generated, stress distributions are also calculated/estimated for the piezoresistive force sensor 10 subject to a 1° C. temperature increase applied to the piezoresistive force sensor 10 by utilizing the FEA model (step 104_2). FIG. 5 illustrates a temperature-induced stress (TIS) map 22 of the piezoresistive force sensor 10, which indicates the stress distributions throughout the entire piezoresistive force sensor 10 (in the horizontal plane) when the 1° C. temperature increase is applied to the piezoresistive force sensor 10. In different applications, different temperature changes may be used in the simulation.

Due to the non-uniform structure of the piezoresistive force sensor 10 (e.g., due to the presence of the solder bumps 14), the mechanical stress induced by the 1° C. temperature increase is uneven across the piezoresistive force sensor 10. For the purpose of this illustration, the lowest stress levels induced by the 1° C. temperature increase (minimum positive stress or minimum negative stress) occur around outer areas of the piezoresistive force sensor 10 and around boundaries of each solder bump 14. In different applications, the lowest stress levels induced by the 1° C. temperature increase may occur at different locations on the piezoresistive force sensor 10.

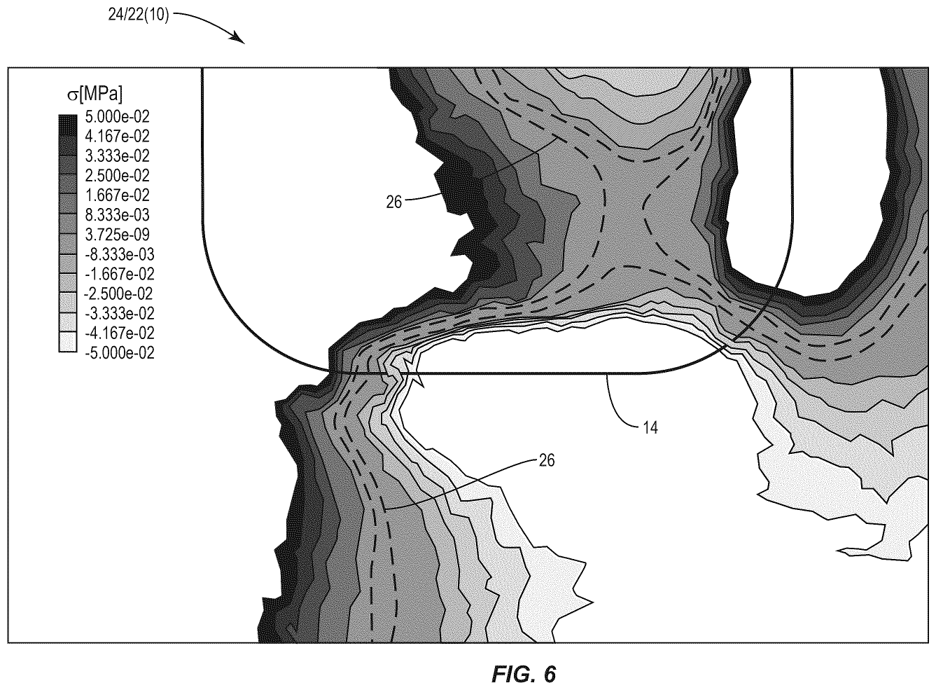

Once the 1° C. temperature-increase-induced stress distributions are calculated (i.e., the TIS map 22 is confirmed), one or more regions, where the absolute value of the 1° C. temperature-increase-induced stress level |σ_{F}| is smaller than or equal to σₘₐₓ, are plotted (step 106_2). σₘₐₓ is a positive number and is the maximum tolerable stress level corresponding to the applied 1° C. temperature increase (e.g., σₘₐₓ=1.5e-02 MPa). In some embodiments, the 1° C. temperature-increase-induced stress level σ_{T} can be acceptable between σ₁ and σ₂ (σ₁≤σ_{T}≤σ₂). σ₁ is a maximum negative stress level and σ₂ is a maximum positive stress level. σ₁ and σ₂ may have a same or different absolute value, but both are close to zero. FIG. 6 illustrates an enlarged portion of a TIS conditional plot 24 with the plotted |σ_{F}|≤σₘₐₓ regions 26 (the TIS map 22 is added as a background for illustrative reference). For the purpose of these illustrations, the plotted |σ_{F}|≤σₘᵢₙ regions 26 are composed of multiple strips. In different applications, the plotted |σ_{F}|≤σₘᵢₙ regions 26 may have different shapes and/or different sizes depending on the temperature-increase-induced stress distributions on the piezoresistive force sensor 10.

Note that calculating the stress distributions subject to the 1N force input (step 104_1) and generating the FIS conditional plot 18 (step 106_1) may be performed before, after, or at the same time as calculating the stress distributions subject to the 1° C. temperature increase (step 104_2) and generating the TIS conditional plot 24 (step 106_2). In addition, calculating the stress distributions subject to the 1N force input (step 104_1) and generating the FIS conditional plot 18 (step 106_1) are independent from calculating the stress distributions subject to the 1° C. temperature increase (step 104_2) and generating the TIS conditional plot 24 (step 106_2).

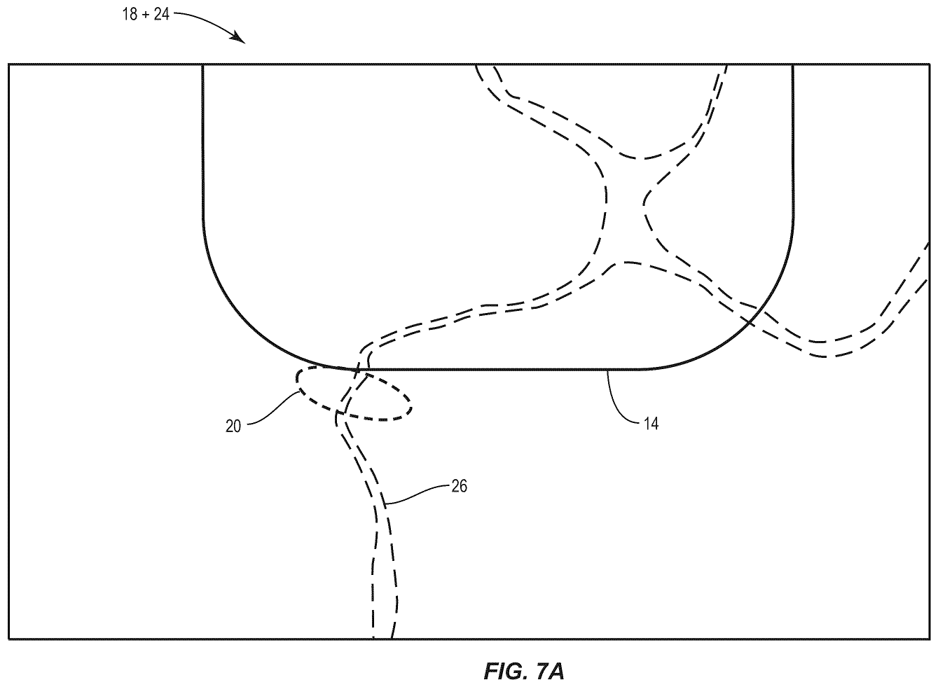

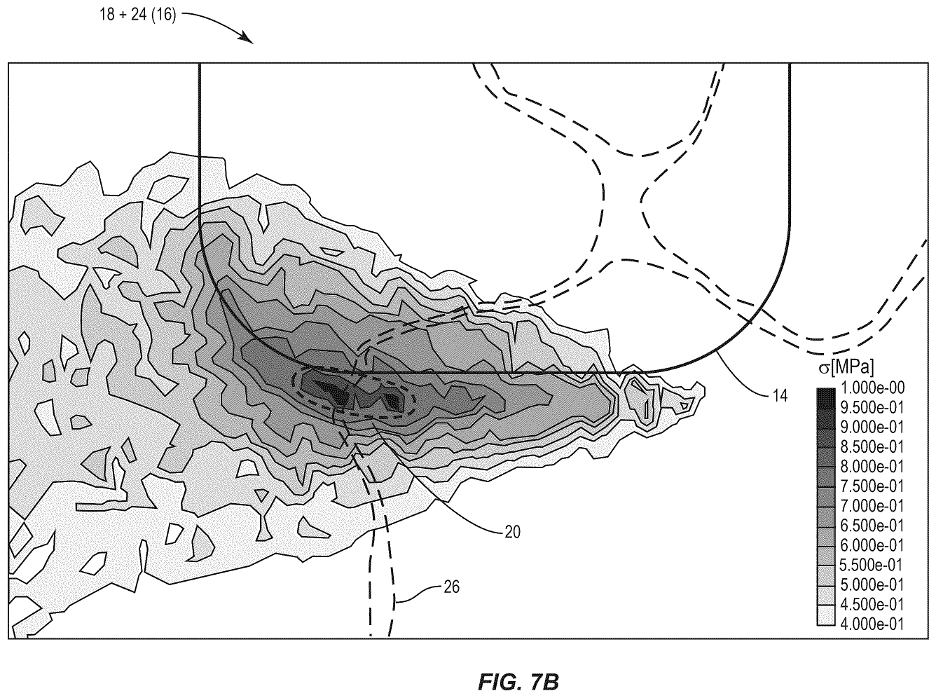

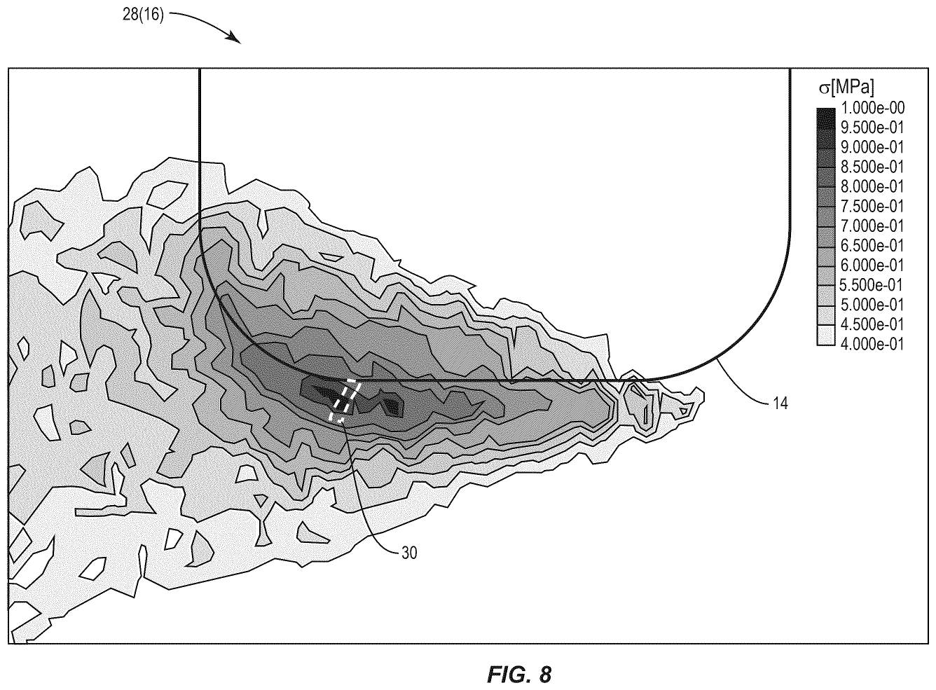

After both the FIS conditional plot 18 and the TIS conditional plot 24 are generated, an intersection plot is then generated by overlaying the FIS conditional plot 18 and the TIS conditional plot 24 (step 108), so as to determine specific locations within the piezoresistive force sensor 10 at which the stress levels OF and GT of the piezoresistive force sensor 10 simultaneously meet FIS and TIS requirements (i.e., satisfying both |σ_{F}|≥σₘᵢₙ and |σ_{F}|≤σₘₐₓ). FIG. 7A shows a portion of the overlap between the FIS conditional plot 18 and the TIS conditional plot 24, while FIG. 7B illustrates the overlap with the FIS map 16 as a background for illustrative reference. In addition, FIG. 8 shows a portion of a result intersection plot 28 (with the FIS map 16 as a background for illustrative reference), which indicates whether there is any solution region that meets both FIS and TIS requirements, how many solution regions meet both FIS and TIS requirements, and where these solution regions are. For the purpose of this illustration, each solution region 30 within the intersection plot 28 has a trapezoidal shape. In different applications, the solution regions 30 may have different shapes, sizes, and/or numbers depending on the intersection results. The intersection plot 28 ensures each solution region 30, if existent, is an optimal region for placing the piezoresistors. If the intersection plot is empty (i.e., no solution region 30), then there is no location within the piezoresistive force sensor 10 that satisfies both the FIS and TIS requirements for placing the piezoresistors. Lastly, if the intersection plot is not empty, one or more piezoresistors are placed in each solution region 30 of the intersection plot 28 (step 110, not shown).

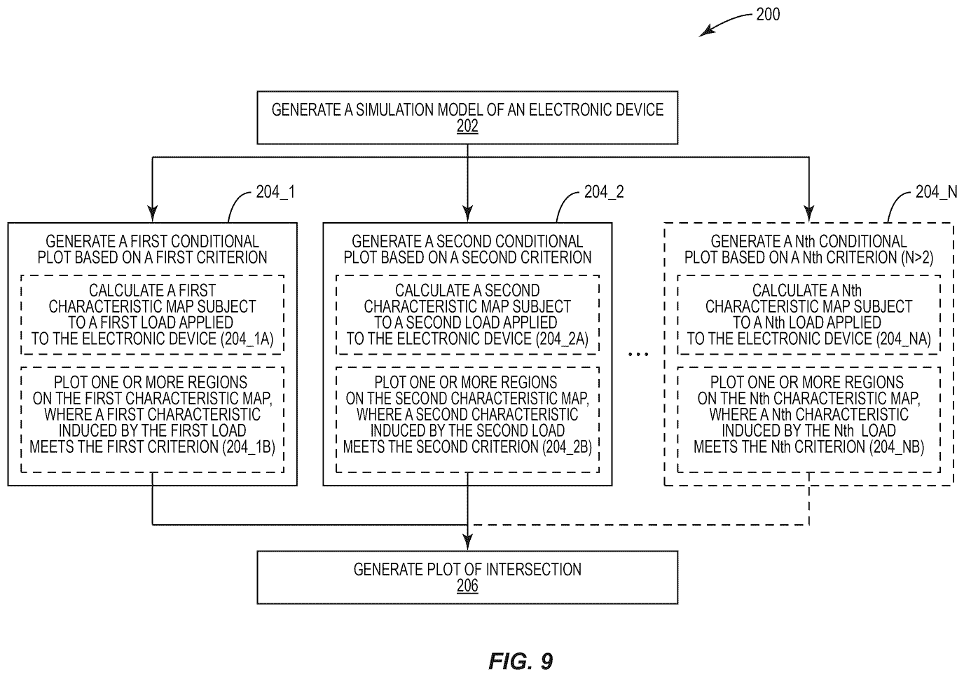

Similar concepts as described above can also be applied to other electronic devices (such as piezoresistive pressure sensors, piezoresistive microphones, piezoresistive accelerometers, or any other piezoresistive sensors, or devices other than sensors, such as actuators). FIG. 9 provides a flow diagram that illustrates an exemplary process 200 to determine an optimal solution for an electronic device according to some embodiments of the present disclosure.

Initially, a simulation model (e.g., the FEA model) of an electronic device (e.g., the piezoresistive force sensor 10) is generated (step 202). The simulation model is configured to simulate one or more types of characteristics of the electronic device for different loads applied to the electronic device. For a piezoresistive sensor, the simulation model is configured to simulate stress levels induced from different loads (e.g., electrical inputs, thermal inputs, mechanical inputs, magnetic inputs, and/or optical inputs) applied to the electronic device. For an optical sensor, the simulation model is configured to simulate current induced from different sources (e.g., a desired photocurrent from light and an undesired thermal leakage current from temperature change).

Next, a first conditional plot (e.g., the FIS conditional plot 18) of the electronic device is generated based on a first criterion by the simulation model (step 204_1). Herein, a first characteristic (e.g., the 1N force-induced stress level σ_{F}) within the first conditional plot is required to meet the first criterion (e.g., |σ_{F}|≥σₘᵢₙ) when a first load (e.g., the 1N force) is applied to the electronic device. In some applications, generating the first conditional plot includes calculating a first characteristic map (e.g., the FIS map 16) of the electronic device subject to the first load applied to the electronic device (step 204_1A) and plotting one or more regions on the first characteristic map within which the first characteristic induced by the first load meets the first criterion (step 2041B).

Similarly, a second conditional plot (e.g., the TIS conditional plot 24) of the electronic device is generated based on a second criterion by the simulation model (step 204_2). Herein, a second characteristic (e.g., the 1° C. temperature-increase-induced stress level GT) within the second conditional plot is required to meet the second criterion (e.g., |σ_{F}|≤σₘₐₓ) when a second load (e.g., 1° C. temperature increase) is applied to the electronic device. In some applications, generating the second conditional plot includes calculating a second characteristic map (e.g., the TIS map 22) of the electronic device subject to the second load applied to the electronic device (step 204_2A) and plotting one or more regions on the second characteristic map within which the second characteristic induced by the second load meets the second criterion (step 204_2B).

Note that generating the second conditional plot (step 204_2) may be performed before, after, or at the same time as generating the first conditional plot (step 204_1) and is independent from generating the first conditional plot (step 204_1). In some embodiments, there might be more than two conditional plots generated utilizing a similar calculating and plotting strategy. For instance, an N^{th} conditional plot of the electronic device is generated based on an N^{th} criterion by the simulation model (step 204_N). These additional conditional plots can be generated in any sequence, and may be generated before, after, or at the same time as the first/second conditional plot. These additional conditional plots are generated independently from each other and independently from the first/second conditional plot.

In some applications, generating the N^{th} conditional plot includes calculating a N^{th} characteristic map of the electronic device subject to a N^{th} load applied to the electronic device (step 204_NA) and plotting one or more regions on the N^{th} characteristic map within which a N^{th} characteristic induced by the N^{th} load meets the N^{th} criterion (step 204_NB). In some applications, the first load, the second load, and the N^{th} load are different from each other, while the first characteristic, the second characteristic, and the N^{th} characteristic are a same type of characteristic. In some applications, the first load, the second load, and the N^{th} load are different from each other, and the first characteristic, the second characteristic, and the N^{th} characteristic include more than one type of characteristic (e.g., the first characteristic is the same type as the N^{th} characteristic, but different from the second characteristic, or the first characteristic, the second characteristic, and the N^{th} characteristic are different from each other).

After the first conditional plot, the second conditional plot, and the optional additional conditional plot(s) are generated, an intersection plot (e.g., the intersection plot 28) is then generated by overlaying the first conditional plot, the second conditional plot, and the optional additional conditional plot(s) (step 206), so as to determine solution locations within the electronic device, at which the first, second, and additional characteristics of the electronic device meet the first, second, and additional criteria (e.g. satisfying |σ_{F}|≥σₘᵢₙ and |σ_{F}|≤σₘₐₓ), respectively.

The systems and methods for determining optimal solutions for a piezoresistive sensor, according to aspects disclosed herein, may be provided in designing any electronic device with a physical interface component (e.g., interface button). Examples, without limitation, include a communications device, a navigation device, a fixed location data unit, a mobile location data unit, a global positioning system (GPS) device, a mobile phone, a cellular phone, a smartphone, a session initiation protocol (SIP) phone, a tablet, a phablet, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

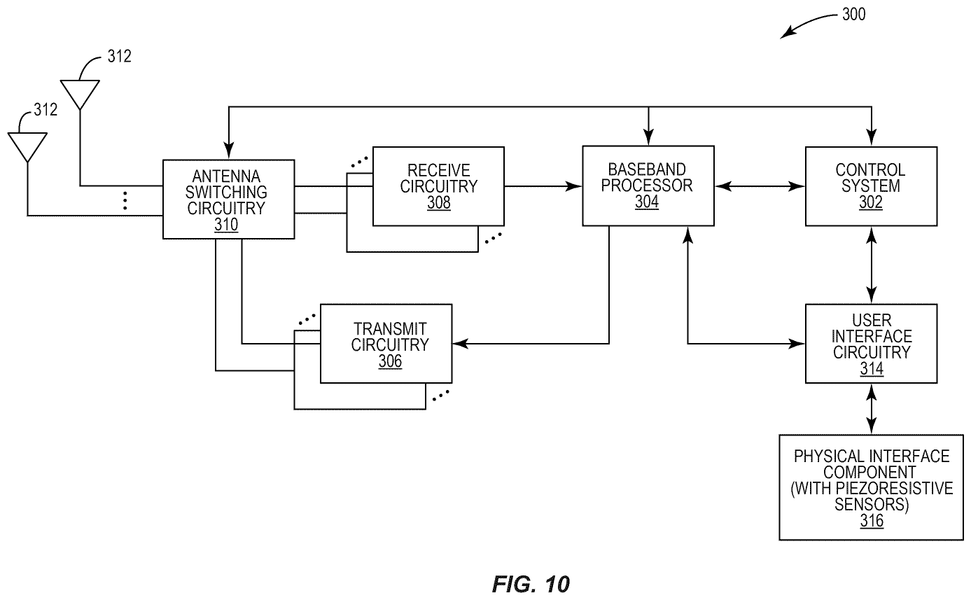

With reference to FIG. 10, the concepts described above may be utilized in designing various types of communication devices 300, such as those listed in the previous paragraph. The communication device 300 will generally include a control system 302, a baseband processor 304, transmit circuitry 306, receive circuitry 308, antenna switching circuitry 310, multiple antennas 312, user interface circuitry 314, and a physical interface component 316. Herein, one or more piezoresistive sensors are included in the physical interface component 316, which are designed by utilizing the process described above.

In a non-limiting example, the control system 302 can be a field-programmable gate array (FPGA) or an application-specific integrated circuit (ASIC), as an example. In this regard, the control system 302 can include at least a microprocessor(s), an embedded memory circuit(s), and a communication bus interface(s). The receive circuitry 308 receives radio frequency signals via the antennas 312 and through the antenna switching circuitry 310 from one or more base stations. A low noise amplifier and a filter of the receive circuitry 308 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 304 processes the digitized received signal to extract the information or data bits conveyed in the received signal. This processing typically comprises demodulation, decoding, and error correction operations, as will be discussed in greater detail below. The baseband processor 304 is generally implemented in one or more digital signal processors (DSPs) and ASICs.

For transmission, the baseband processor 304 receives digitized data, which may represent voice, data, or control information, from the control system 302, which it encodes for transmission. The encoded data is output to the transmit circuitry 306, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 312 through the antenna switching circuitry 310. The multiple antennas 312 and the replicated transmit and receive circuitries 306, 308 may provide spatial diversity. Modulation and processing details will be understood by those skilled in the art.

In addition, the physical interface component 316 includes one or more piezoresistive sensors, which are configured to measure external loads applied to the physical interface component 316 and to transfer electrical signals to the user interface circuitry 314 corresponding to the external loads. The user interface circuitry 314 may communicate with the baseband processor 304 and/or the control system 302, such that the electrical signals induced by the external loads are processed in the baseband processor 304 and/or the control system 302.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method of determining an optimal solution for an electronic device comprising:
generating a first conditional plot of the electronic device based on a first criterion, wherein a first characteristic within the first conditional plot meets the first criterion when a first load is applied to the electronic device;
generating a second conditional plot of the electronic device based on a second criterion, wherein:
a second characteristic within the second conditional plot meets the second criterion when a second load is applied to the electronic device;
the second criterion is different from the first criterion; and
generating the second conditional plot is independent from generating the first conditional plot; and
generating an intersection plot by overlaying the first conditional plot with the second conditional plot, wherein the intersection plot indicates whether the electronic device has one or more solution regions that satisfy both the first criterion and the second criterion.

2. The method of claim 1 wherein:
the first load is different from the second load; and
the first characteristic and the second characteristic are a same type of characteristic.

3. The method of claim 2 wherein each of the first load and the second load is one of an electrical input, a thermal input, a mechanical input, and a magnetic input.

4. The method of claim 1 wherein the first characteristic is different from the second characteristic.

5. The method of claim 1 further comprising before generating the intersection plot, generating one or more additional conditional plots of the electronic device based on one or more additional criteria, respectively, wherein the one or more additional criteria are different from the first criterion and the second criterion.

6. The method of claim 5 wherein:
generating the one or more additional conditional plots is independent from generating the first conditional plot and generating the second conditional plot; and
the intersection plot is generated by overlaying the first conditional plot, the second conditional plot, and the one or more additional conditional plots, wherein the intersection plot indicates whether the electronic device has one or more solution regions that satisfy the first criterion, the second criterion, and the one or more additional criteria.

7. The method of claim 1 wherein generating the first conditional plot of the electronic device comprises:
calculating a first characteristic map of the electronic device subject to the first load applied to the electronic device; and
plotting one or more regions on the first characteristic map, within which the first characteristic induced by the first load meets the first criterion.

8. The method of claim 7 wherein generating the second conditional plot of the electronic device comprises:
calculating a second characteristic map of the electronic device subject to the second load applied to the electronic device; and
plotting one or more regions on the second characteristic map, within which the second characteristic induced by the second load meets the second criterion.

9. The method of claim 1, wherein:
the electronic device is a piezoresistive sensor;
the first characteristic is a first stress level induced by the first load;
the second characteristic is a second stress level induced by the second load; and
the first load and the second load are different, each of which is one of an electrical input, a thermal input, a mechanical input, a magnetic input, and an optical input.

10. The method of claim 1, wherein:
the electronic device is an optical sensor;
the first characteristic is a first current induced by the first load;
the second characteristic is a second current induced by the second load; and
the first load and the second load are different, each of which is one of an optical input and a thermal input.

11. The method of claim 1, wherein when the one or more solution regions exist, the intersection plot further indicates how many solution regions satisfy both the first criterion and the second criterion, and where the one or more solution regions are located.

12. A method of determining an optimal solution for a piezoresistive force sensor comprising:
generating a force-induced stress (FIS) conditional plot of the piezoresistive force sensor based on a first criterion, wherein an FIS level within the FIS conditional plot meets the first criterion when a force input is applied to the piezoresistive force sensor;
generating a temperature-induced stress (TIS) conditional plot of the piezoresistive force sensor based on a second criterion, wherein:
a TIS level within the TIS conditional plot meets the second criterion when a temperature increase is applied to the piezoresistive force sensor; and
generating the TIS conditional plot is independent from generating the FIS conditional plot; and
generating an intersection plot by overlaying the FIS conditional plot with the TIS conditional plot, wherein the intersection plot indicates whether the piezoresistive force sensor has one or more solution regions that satisfy both the first criterion and the second criterion.

13. The method of claim 12 wherein:
the first criterion is that an absolute value of the FIS level is larger than a minimum required value corresponding to the applied force input; and
the second criterion is that an absolute value of the TIS level is smaller than a maximum required value corresponding to the applied temperature increase.

14. The method of claim 12 wherein generating the FIS conditional plot comprises:
calculating stress distributions for the piezoresistive force sensor subject to the force input applied to the piezoresistive force sensor, such that an FIS map of the piezoresistive force sensor is confirmed; and
plotting one or more regions on the FIS map, within which the FIS level meets the first criterion.

15. The method of claim 14 wherein generating the TIS conditional plot comprises:
calculating stress distributions for the piezoresistive force sensor subject to the temperature increase applied to the piezoresistive force sensor, such that a TIS map of the piezoresistive force sensor is confirmed; and
plotting one or more regions on the TIS map, within which the TIS level meets the second criterion.

16. The method of claim 15 wherein:
the first criterion is that an absolute value of the FIS level is larger than a minimum required value corresponding to the applied force input; and
the second criterion is that an absolute value of the TIS level is smaller than a maximum required value corresponding to the applied temperature increase.

17. The method of claim 12, wherein when the one or more solution regions exist, the intersection plot further indicates how many solution regions satisfy both the first criterion and the second criterion, and where the one or more solution regions are located.

18. The method of claim 17 further comprising placing piezoresistors in the one or more solution regions of the piezoresistive force sensor.

19. A communication device comprising:
a control system;
a baseband processor;
user interface circuitry configured to communicate with the baseband processor and/or the control system; and
a physical interface component including at least one piezoresistive sensor, which is configured to measure external loads to the physical interface component and to transfer electrical signals to the user interface circuitry corresponding to the external loads, such that the electrical signals induced by the external loads are capable of being processed in the baseband processor and/or the control system, wherein measuring the external loads comprises:
generating a first conditional plot of the at least one piezoresistive sensor, based on a first criterion, wherein a first characteristic within the first conditional plot meets the first criterion when a first load of the external loads is applied to the at least one piezoresistive sensor;
generating a second conditional plot of the at least one piezoresistive sensor based on a second criterion, wherein:
a second characteristic within the second conditional plot meets the second criterion when a second load of the external loads is applied to the at least one piezoresistive sensor;
the second criterion is different from the first criterion; and
generating the second conditional plot is independent from generating the first conditional plot; and
generating an intersection plot by overlaying the first conditional plot with the second conditional plot, wherein the intersection plot indicates whether the at least one piezoresistive sensor has one or more solution regions that satisfy both the first criterion and the second criterion.
